(19) United States
(12) Patent Application Publication
(10) Pub. No.: US 2013/0143042 A1
(43) Pub. Date: Jun. 6, 2013

(54) Ultra-High Strength, Corrosion Resistant Wire, a Method of Making Same, and a Method of Using Same

(71) Applicant: CRS Holdings, Inc., Wilmington, DE (US)

(72) Inventors: Richard B. Frank, Reading, PA (US); Lyndon W. Burleson, Orangeburg, SC (US)

(73) Assignee: CRS HOLDINGS, INC., Wilmington, DE (US)

(21) Appl. No.: 13/705,781

(22) Filed: Dec. 5, 2012

Related U.S. Application Data
(63) Continuation of application No. 12/721,844, filed on Mar. 11, 2010, now abandoned.
(60) Provisional application No. 61/159,577, filed on Mar. 12, 2009.

(51) Int. Cl. H05K 9/00; B32B 15/02

(52) U.S. Cl. CPC H05K 9/0098; B32B 15/02
USPC 428/371; 420/586

(57) ABSTRACT

A method of making steel wire includes the step of forming a length of wire from an alloy that preferably contains in weight percent:

| | |
|---|---|
| Carbon | 0.03 max. |
| Manganese | 0.15 max. |
| Silicon | 0.15 max. |
| Phosphorus | 0.015 max. |
| Sulfur | 0.010 max. |
| Chromium | 19.00-21.00 |
| Nickel | 33.00-37.00 |
| Molybdenum | 9.00-10.50 |
| Titanium | 1.00 max. |
| Boron | 0.010 max. |
| Iron | 1.00 max. |

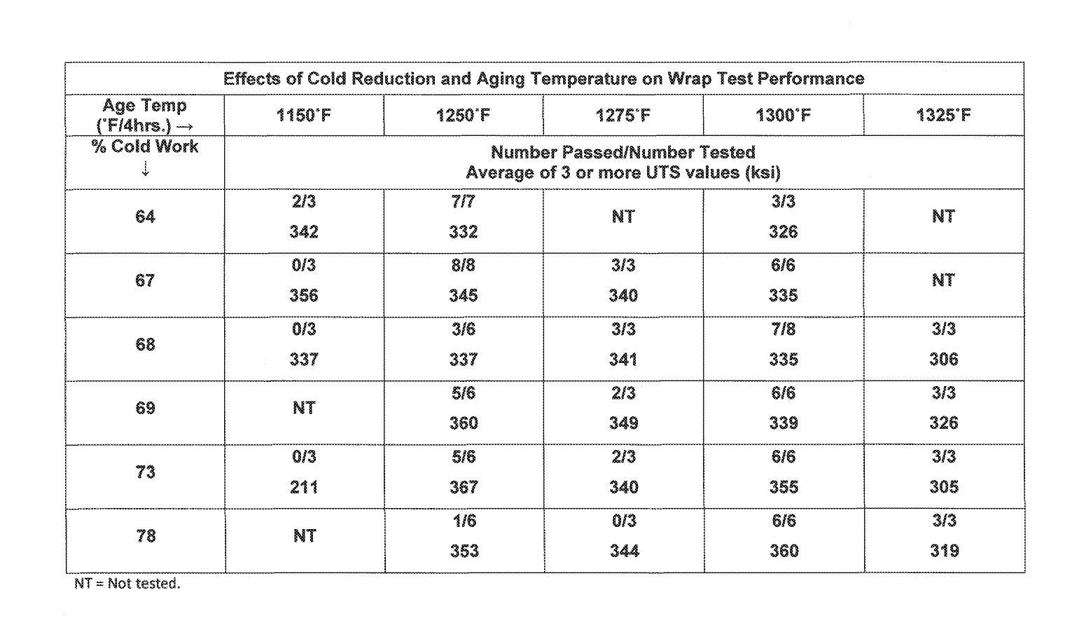

The balance is cobalt and usual impurities. The wire is annealed at a combination of temperature and time effective to provide a grain size of about ASTM 6 or finer and is then drawn to provide a reduction in cross-sectional area of about 50 to 80%. The wire is—then heat treated under temperature and time conditions effective to provide the wire with high strength and sufficient wrap ductility that the wire does not crack or break in a standardized wrap test.

### CROSS-REFERENCE TO RELATED APPLICATIONS

This application is a continuation of copending application Ser. No. 12/721,844, filed Mar. 11, 2010, which claims the benefit of U.S. Provisional Application No. 61/159,577, filed Mar. 12, 2009, the entireties of which are incorporated herein by reference.

### BACKGROUND OF THE INVENTION

1. Field of the Invention

This invention generally relates to fine gauge, high strength wire, and in particular, it relates to a wire product that provides a unique combination of very high strength, excellent ductility, and good corrosion resistance for use in armored cable.

2. Description of the Related Art

Armored communication cable has been used for transmission of communication and control signals to equipment operating in oil wells, particularly in deep sour gas wells. One type of armored cable for the oil well application is described in U.S. Pat. No. 6,255,592, the entire disclosure of which is incorporated herein by reference. Typically, the armor portion of such cables is made from steel wire that contains a medium to high amount of carbon. It is also known to use stainless steel wire for the armoring portion of armored cable used in oil wells. The wire used for making armored cable sheath is typically used at a tensile strength level of 275-295 ksi. However, the users of such cables are now demanding even higher strength levels for this application.

The alloy designated UNS R00035 is a corrosion resistant Ni—Co base alloy that provides a tensile strength of up to about 300 ksi. At least one specification for cable armor requires the use of the UNS R00035 alloy. However, when that alloy is processed to produce wire having a tensile strength in excess of 300 ksi, the alloy lacks sufficient ductility to resist breaking in a standard wire-wrap test. Accordingly, it would be advantageous to produce a corrosion resistant Ni—Co base alloy wire that can be processed to wire form, that provides a tensile strength in excess of 300 ksi, and which also provides sufficient ductility to meet the wire-wrap test.

### SUMMARY OF THE INVENTION

In accordance with a first aspect of the present invention there is provided a method of making steel wire. The method according to this invention includes the step of forming a length of wire from a high strength, corrosion resistant alloy. The alloy preferably has the following composition in weight percent.

| | |
|---|---|
| Carbon | 0.03 max. |
| Manganese | 0.15 max. |
| Silicon | 0.15 max. |
| Phosphorus | 0.015 max. |
| Sulfur | 0.010 max. |
| Chromium | 19.00-21.00 |
| Nickel | 33.00-37.00 |
| Molybdenum | 9.00-10.50 |
| Titanium | 1.00 max. |
| Boron | 0.010 max. |
| Iron | 1.00 max. |

The balance of the alloy is cobalt and usual impurities. The wire is annealed at a combination of temperature and time effective to provide a grain size of about ASTM 6 or finer. The annealed wire is then drawn such that the cross-sectional area of the wire is reduced by about 50 to 80%. The as-drawn wire is then heat treated at a second combination of temperature and time effective to provide the wire with high strength and sufficient ductility that when the wire is wrapped to provide a coil having an inside diameter substantially commensurate with the diameter of the wire and then unwrapped, the wire does not crack or break.

In accordance with another aspect of the present invention there is provided a method of making flexible armored cable. This method includes the step of forming a length of wire from an alloy comprising, in weight percent, about

| | |
|---|---|
| Carbon | 0.03 max. |
| Manganese | 0.15 max. |
| Silicon | 0.15 max. |
| Phosphorus | 0.015 max. |
| Sulfur | 0.010 max. |
| Chromium | 19.00-21.00 |
| Nickel | 33.00-37.00 |
| Molybdenum | 9.00-10.50 |
| Titanium | 1.00 max. |
| Boron | 0.010 max. |
| Iron | 1.00 max. |

The balance of the alloy is cobalt and the usual impurities. The wire is then annealed at a combination of temperature and time effective to provide a grain size of about ASTM 6 or finer. The annealed wire is then drawn such that the cross-sectional area of the wire is reduced by about 50 to 80%. The wire is then heat treated at a second combination of temperature and time that is effective to provide the alloy with high strength and sufficient ductility that when the wire is wrapped to provide a coil having an inside diameter substantially commensurate with the diameter of the wire and then unwrapped, the wire does not crack or break. The heat treated wire is then helically wound around an elongated core member to form a flexible encasement around the elongated core member.

In accordance with a further aspect of the present invention, there is provided a wire formed from a high strength, corrosion resistant alloy having the following composition in weight percent, about

| | |
|---|---|
| Carbon | 0.03 max. |
| Manganese | 0.15 max. |
| Silicon | 0.15 max. |
| Phosphorus | 0.015 max. |
| Sulfur | 0.010 max. |
| Chromium | 19.00-21.00 |
| Nickel | 33.00-37.00 |
| Molybdenum | 9.00-10.50 |
| Titanium | 1.00 max. |
| Boron | 0.010 max. |
| Iron | 1.00 max. |

The balance of the alloy is cobalt and the usual impurities. The wire is characterized by a tensile strength in excess of 300 ksi and sufficient ductility that when the wire is wrapped to provide a coil having an inside diameter substantially equal to the diameter of the wire and then unwrapped, the wire does not crack or break.

Here and throughout this specification the following definitions apply unless otherwise indicated. The term “percent” and the symbol “%” are used in expressing weight percent, mass percent, or percent reduction in cross-sectional area, except as otherwise indicated. ASTM grain size numbers are those determined in accordance with ASTM Standard E112-96(2004), “Standard Test Methods for Determining Average Grain Size” (DOI: 10.1520/E0112-96R04).

### BRIEF DESCRIPTION OF THE DRAWING

The drawing figure is a chart that shows the effects of cold working and aging temperature on the ultimate tensile strength and wrap test performance of high strength wire.

### DETAILED DESCRIPTION

In accordance with the present invention, the known composition and the known processing of UNS R00035 alloy are modified to provide a wire product having a novel combination of tensile strength and ductility as well as good corrosion resistance. In accordance with the first step in the process according to this invention, an alloy having the following weight percent composition is melted, refined, and cast into an ingot mold.

| | |
|---|---|
| Carbon | 0.03 max. |
| Manganese | 0.15 max. |
| Silicon | 0.15 max. |
| Phosphorus | 0.015 max. |
| Sulfur | 0.010 max. |
| Chromium | 19.00-21.00 |
| Nickel | 33.00-37.00 |
| Molybdenum | 9.00-10.50 |
| Titanium | 1.00 max. |
| Boron | 0.010 max. |
| Iron | 1.00 max. |
| Cobalt + Impurities | Balance |

The ingot is removed from the mold upon solidification and then mechanically worked into intermediate product forms having progressively smaller cross sections. Processes for melting, casting, and mechanically working the alloy are known and described in U.S. Pat. No. 3,356,542 and U.S. Pat. No. 3,562,042, the entire disclosures of which are incorporated herein by reference. It is believed that a low Ti grade of this alloy, i.e., 0.01% max. Ti, will also provide acceptable results.

The process according to this invention is designed to produce a wire product from the alloy which has a fine, recrystallized grain structure prior to cold drawing. Commercial specifications for the UNS R00035 alloy, such as AMS 5844 which relates to bar products, require an annealing treatment at 1900-1925° F. for 4 to 8 hours. That annealing heat treatment provides a medium grain size in the range of ASTM 4 to 6. We have discovered that a lower annealing temperature, preferably about 1750-1850° F. provides a finer grain size (ASTM 6 or finer) which is believed to result in a better combination of strength and ductility even when the alloy is in the cold-worked condition. The annealing step is preferably carried out for about 0.5 to 2 hours. After solution annealing, the alloy is heavily cold drawn in the range of about 50-80% reduction in cross-sectional area (R.C.S.A.), preferably about 65-75% R.C.S.A. to obtain a tensile strength exceeding about 300 ksi. Typically, armoring cable products are then used in the as-cold-drawn condition. Another aspect of this invention is to age-harden the alloy wire at a temperature of 900-1400° F. to improve the overall combination of strength and ductility. In the age-hardened condition, the alloy provides an ultimate tensile strength of at least about 310 ksi together with excellent ductility as demonstrated by the wire's resistance to breaking in the wrap test. Furthermore, it is also believed that overaging the wire at a temperature greater than 1100° F. provides better ductility than the standard aging temperature of 1000-1050° F.

The processing steps used to obtain the desired combination of strength and bendability do not appear to adversely affect the corrosion resistance provided by the alloy used to make wire products in accordance with this invention. However, it is believed that the corrosion resistance of the wire product is affected by the cleanliness of the wire surface after processing. Therefore, the annealing and aging heat treatments of the wire are preferably carried out under a subatmospheric pressure to substantially avoid oxidation or other contamination of the wire surface. A subatmospheric pressure of less than about 1 torr (130 Pa) is preferred.

### WORKING EXAMPLES

### Example 1

Experimental trials were performed using 0.0565 in rd. wire from a triple melted heat having the weight percent composition set forth in Table I below. Triple melting is a known technique that includes the steps of vacuum induction melting (VIM), followed by electroslag remelting (ESR), and then vacuum arc remelting (VAR). The wire was annealed at subatmospheric pressure at 1800° F. for 90 minutes and then quenched in argon gas. The grain size of the annealed wire was about ASTM size 6-8. Wire samples cut from the annealed coils were cold drawn to 50%, 55%, 60%, 64%, and 67% reductions in cross-sectional area (R.C.S.A.) to provide wire diameters of 0.040 in., 0.038 in., 0.036 in., 0.034 in., and 0.032 in., respectively. Cold drawing is performed with the wire at room (ambient) temperature. The wire samples were then aged at temperatures in the range of 1050° F.-1250° F. in argon-filled SEN/PAK® heat treating containers. Fine wire tensile tests and wrap tests were conducted to determine the strength and ductility of the wire. The wrap test consists of wrapping the wire around its own circumference five times followed by unwrapping. The test sample passes if the wire does not crack or break during wrapping or unwrapping.

TABLE I

| Element | Example 1 | Example 2 |
|---|---|---|
| C | 0.010 | 0.008 |
| Mn | 0.01 | 0.01 |
| Si | 0.03 | 0.03 |
| P | 0.002 | <0.001 |
| S | 0.002 | 0.002 |
| Cr | 20.75 | 20.57 |
| Ni | 34.76 | 34.75 |
| Mo | 9.53 | 9.52 |
| Co | 33.36 | 33.86 |
| Cb | 0.03 | 0.06 |
| Al | 0.12 | — |
| Ti | 0.81 | 0.76 |
| B | 0.0096 | 0.0106 |
| Fe | 0.50 | 0.45 |
| O | <10 ppm | — |
| N | 41 ppm | 41 ppm |

Initial results were promising for the greatest cold reduction used (67%) and for the higher aging temperatures. Additional testing was conducted using R.C.S.A.'s of 69%, 73%, and 78% and aging temperatures up to 1350° F. Tables II and III below show the results of the room temperature tensile and wrap tests for the cold-drawn and aged fine wire samples including the 0.2% offset yield strength (0.2% Y.S.) and the ultimate tensile strength (U.T.S.) in ksi, the percent elongation (% El.), and the reduction in cross-sectional area (%R.A.). It should be noted that the tensile ductility values are approximate because of the difficulty in measuring the percent elongation and percent reduction in area of fine wire samples.

TABLE II

| Wire | % Cold | Aging | 0.2% | | | | |
|---|---|---|---|---|---|---|---|
| Diameter | Drawn | Treatment | Y.S. | U.T.S. | % El. | % R.A. | Wrap Test |
| 0.0565 in. | 0 | None | 66 | 156 | 50 | 54 | passed |
| ″ | 0 | | 67 | 157 | 48 | 54 | |
| ″ | 0 | | 68 | 159 | 48 | 54 | |
| 0.040 in. | 50 | None | 207 | 268 | 5 | — | passed |
| ″ | 50 | ″ | 214 | 269 | 5 | — | |
| ″ | 50 | ″ | 215 | 268 | 5 | — | |
| ″ | 50 | 1050° F./4 h/AC | 313 | 323 | 3 | 67 | passed |
| ″ | 50 | ″ | 305 | 317 | 3 | 67 | passed |
| ″ | 50 | ″ | 313 | 323 | 3 | 67 | |
| ″ | 50 | 1150° F./4 h/AC | 305 | 309 | 1 | 40 | passed |
| ″ | 50 | ″ | 306 | 308 | 1 | 40 | passed |
| ″ | 50 | ″ | 305 | 307 | 1 | 32 | passed |
| ″ | 50 | 1250° F./4 h/AC | 279 | 286 | 1 | 32 | passed |
| ″ | 50 | ″ | 287 | 290 | 1 | 36 | passed |
| ″ | 50 | ″ | 288 | 292 | 1 | 44 | passed |
| 0.038 in. | 55 | None | 200 | 279 | 3 | 60 | passed |
| ″ | 55 | ″ | 196 | 279 | 3 | 60 | |
| ″ | 55 | ″ | 198 | 279 | 3 | 60 | |
| ″ | 55 | 1050° F./4 h/AC | 317 | 331 | 2 | 45 | failed |
| ″ | 55 | ″ | 327 | 340 | 2 | 45 | failed |
| ″ | 55 | ″ | 322 | 336 | 2 | 45 | |
| 0.038 in. | 55 | 1150° F./4 h/AC | 279 | 325 | 1 | 37 | passed |
| ″ | 55 | ″ | 285 | 327 | 1 | 41 | passed |
| ″ | 55 | ″ | 300 | 327 | 1 | 41 | passed |
| ″ | 55 | 1250° F./4 h/AC | 286 | 301 | 1 | 41 | passed |
| ″ | 55 | ″ | 293 | 309 | 1 | 41 | passed |
| ″ | 55 | ″ | 308 | 312 | 1 | 37 | passed |
| 0.036 in. | 60 | None | 225 | 282 | 4 | — | passed |
| ″ | 60 | ″ | 222 | 280 | 4 | — | passed |
| ″ | 60 | ″ | 225 | 281 | 4 | — | |
| ″ | 60 | 1050° F./4 h/AC | 315 | 344 | 2 | 59 | failed |
| | | | | | | | passed on retest |
| ″ | 60 | ″ | 326 | 345 | 2 | 63 | passed |
| ″ | 60 | ″ | 325 | 342 | 2 | 56 | |
| ″ | 60 | 1150° F./4 h/AC | 329 | 334 | 1 | 36 | passed |
| ″ | 60 | ″ | 315 | 328 | 1 | 36 | passed |
| ″ | 60 | ″ | 311 | 327 | 1 | 32 | passed |
| ″ | 60 | 1250° F./4 h/AC | 317 | 322 | 1 | 45 | passed |
| ″ | 60 | ″ | 307 | 307 | 1 | 50 | passed |
| ″ | 60 | ″ | 307 | 316 | 1 | 54 | passed |
| ″ | 60 | ″ | 322 | 333 | 2 | 45 | passed |
| ″ | 60 | ″ | 311 | 329 | 2 | 49 | |
| ″ | 60 | ″ | 331 | 338 | 2 | 31 | |
| 0.034 in. | 64 | None | 244 | 295 | 4 | 57 | passed |
| ″ | 64 | ″ | 252 | 299 | 4 | 57 | |
| ″ | 64 | ″ | 246 | 295 | 4 | 57 | |
| ″ | 64 | 1050° F./4 h/AC | 348 | 360 | 2 | 49 | did not wrap |
| ″ | 64 | ″ | 343 | 359 | 2 | 50 | failed |
| ″ | 64 | ″ | 349 | 360 | 2 | 50 | |
| ″ | 64 | 1150° F./4 h/AC | 302 | 339 | 2 | 50 | failed |
| 0.034 in. | 64 | ″ | 307 | 341 | 1 | 45 | passed |
| ″ | 64 | ″ | 306 | 345 | 1 | 45 | passed |
| ″ | 64 | 1250° F./4 h/AC | 312 | 318 | 2 | 49 | passed |
| ″ | 64 | ″ | 311 | 317 | 2 | 53 | |
| ″ | 64 | ″ | 304 | 311 | 2 | 49 | |
| ″ | 64 | 1250° F./4 h/AC | 331 | 335 | 2 | 26 | passed |
| ″ | 64 | ″ | 324 | 328 | 1 | 21 | passed |
| ″ | 64 | ″ | 324 | 331 | 1 | 26 | passed |
| ″ | 64 | 1300° F./4 h/AC | 325 | 326 | 1 | 26 | passed |
| ″ | 64 | ″ | 328 | 331 | 1 | 31 | passed |
| ″ | 64 | ″ | 316 | 320 | 1 | 31 | passed |

TABLE III

| Wire | % Cold | Aging | 0.2% | | | | |
|---|---|---|---|---|---|---|---|
| Diameter | Drawn | Treatment | Y.S. | U.T.S. | % El. | % R.A. | Wrap Test |
| 0.0325 in. | 67 | None | 273 | 299 | 3 | — | passed |
| ″ | 67 | ″ | 264 | 304 | 4 | — | |
| ″ | 67 | ″ | 274 | 306 | 3 | — | |
| ″ | 67 | 1050° F./4 h/AC | 337 | 358 | 2 | 58 | did not wrap |
| ″ | 67 | ″ | 340 | 359 | 2 | 54 | failed |
| ″ | 67 | ″ | 335 | 360 | 2 | 58 | |
| ″ | 67 | 1150° F./4 h/AC | 346 | 354 | 1 | 50 | failed |
| ″ | 67 | ″ | 348 | 357 | 1 | 46 | failed |
| ″ | 67 | ″ | 356 | 358 | 1 | 46 | failed |
| ″ | 67 | 1200° F./4 h/AC | 338 | 358 | 1 | 41 | failed |
| ″ | 67 | ″ | 351 | 358 | 1 | 46 | failed |
| ″ | 67 | ″ | 338 | 346 | 1 | 41 | failed |
| ″ | 67 | 1250° F./4 h/AC | 325 | 342 | 3 | 40 | passed |
| ″ | 67 | ″ | 330 | 343 | 2 | 45 | |
| 0.0325 in. | 67 | ″ | 307 | 338 | 2 | 54 | passed |
| ″ | 67 | ″ | 355 | 358 | 1 | 46 | passed |
| ″ | 67 | ″ | 331 | 344 | 1 | 54 | passed |
| ″ | 67 | ″ | 312 | 321 | 1 | 46 | passed |
| ″ | 67 | 1275° F./4 h/AC | | 343 | | | passed |
| ″ | 67 | ″ | | 345 | | | passed |
| ″ | 67 | ″ | | 331 | | | passed |
| ″ | 67 | 1300° F./4 h/AC | 335 | 341 | 1 | 41 | passed |
| ″ | 67 | ″ | 327 | 330 | 1 | 36 | passed |
| ″ | 67 | ″ | 340 | 342 | 1 | 36 | passed |
| ″ | 67 | 1300° F./4 h/AC | 328 | 332 | 1 | 36 | passed |
| ″ | 67 | ″ | 325 | 328 | 1 | 41 | passed |
| ″ | 67 | ″ | 336 | 338 | 1 | 31 | passed |
| ″ | 67 | 1350° F./4 h/AC | 227 | 240 | 4 | 66 | passed |
| ″ | 67 | | 227 | 239 | 4 | 66 | |
| ″ | 67 | | 226 | 241 | 4 | 62 | |
| 0.0316 in. | 69 | None | 278 | 303 | 1 | 47 | passed |
| ″ | 69 | 1250° F./4 h/AC | 356 | 361 | 1 | 27 | passed |
| ″ | 69 | ″ | 362 | 364 | 1 | 27 | failed |
| ″ | 69 | ″ | 350 | 356 | 1 | 22 | passed |
| ″ | 69 | 1275° F./4 h/AC | 346 | 348 | 1 | 32 | passed |
| ″ | 69 | ″ | 339 | 345 | 1 | 22 | failed |
| | | | | | | | on unwrap |
| ″ | 69 | ″ | 348 | 353 | 1 | 27 | passed |
| ″ | 69 | 1300° F./4 h/AC | 325 | 337 | 1 | 32 | passed |
| ″ | 69 | ″ | 321 | 334 | 1 | 27 | passed |
| ″ | 69 | ″ | 343 | 347 | 1 | 33 | passed |
| ″ | 69 | 1325° F./4 h/AC | 329 | 334 | 2 | 42 | passed |
| 0.0316 in. | 69 | ″ | 321 | 328 | 1 | 37 | passed |
| ″ | 69 | ″ | 315 | 316 | 2 | 37 | passed |
| ″ | 69 | 1350° F./4 h/AC | 223 | 235 | 2 | 47 | passed |
| ″ | 69 | ″ | 257 | 266 | 2 | 52 | passed |
| ″ | 69 | ″ | 227 | 238 | 2 | 51 | passed |
| 0.0293 in. | 73 | None | 263 | 306 | 1 | 44 | passed |
| ″ | 73 | 1150° F./4 h/AC | 207 | 213 | 1 | 48 | failed |
| ″ | 73 | ″ | 205 | 207 | 1 | 49 | failed |
| ″ | 73 | ″ | 203 | 213 | 1 | 38 | failed |
| ″ | 73 | 1250° F./4 h/AC | 366 | 370 | 1 | 38 | failed |
| ″ | 73 | ″ | 362 | 365 | 1 | 38 | passed |
| ″ | 73 | ″ | 358 | 366 | 1 | 38 | passed |
| ″ | 73 | 1275° F./4 h/AC | 328 | 334 | 1 | 48 | pass |
| ″ | 73 | ″ | 339 | 341 | 1 | 43 | pass |
| ″ | 73 | ″ | 325 | 345 | 1 | 38 | failed |
| | | | | | | | on unwrap |
| ″ | 73 | 1300° F./4 h/AC | 352 | 357 | 2 | 43 | passed |
| ″ | 73 | ″ | 342 | 353 | 1 | 38 | passed |
| ″ | 73 | ″ | 353 | 356 | 1 | 43 | passed |
| ″ | 73 | 1325° F./4 h/AC | 313 | 320 | 2 | 48 | passed |
| ″ | 73 | ″ | 293 | 303 | 1 | 38 | passed |
| ″ | 73 | ″ | 285 | 292 | 1 | 38 | passed |
| ″ | 73 | 1350° F./4 h/AC | 220 | 234 | 2 | 43 | passed |
| ″ | 73 | ″ | 215 | 237 | 2 | 38 | passed |
| ″ | 73 | ″ | 189 | 213 | 2 | 43 | passed |
| 0.0263 in. | 78 | None | 286 | 320 | 1 | 53 | passed |
| ″ | 78 | 1250° F./4 h/AC | 350 | 358 | 1 | 53 | failed |
| ″ | 78 | ″ | 328 | 346 | 1 | 42 | failed |
| 0.0263 in. | 78 | ″ | 350 | 355 | 1 | 53 | failed |
| ″ | 78 | 1275° F./4 h/AC | 337 | 352 | 1 | 47 | failed |
| ″ | 78 | ″ | 332 | 338 | 1 | 42 | failed |
| ″ | 78 | ″ | 339 | 343 | 1 | 42 | failed |
| ″ | 78 | 1300° F./4 h/AC | 347 | 362 | 1 | 17 | passed |
| ″ | 78 | ″ | 352 | 357 | 1 | 17 | passed |
| ″ | 78 | ″ | 358 | 362 | 1 | 30 | passed |
| ″ | 78 | 1325° F./4 h/AC | 314 | 317 | 2 | 53 | passed |
| ″ | 78 | ″ | 319 | 320 | 2 | 48 | passed |
| ″ | 78 | ″ | 317 | 319 | 2 | 53 | passed |
| ″ | 78 | 1350° F./4 h/AC | 210 | 214 | 10 | 48 | passed |
| ″ | 78 | ″ | 182 | 214 | 12 | 48 | passed |
| ″ | 78 | ″ | 180 | 213 | 9 | 53 | passed |

Some of the aged wire samples representing cold reductions of 67-78% and aging treatments of 1250° F./4 hours and 1300° F./4 hours, respectively, were heated at 500° F. to simulate oil well conditions. Table IV shows the room-temperature tensile and wrap test results for the aged wire samples with and without the exposures at 500° F. for 24 hours and for 30 days at 500° F. The results presented in Table IV indicate that the simulated well-aged exposures at 500° F. had no detrimental effect on the tensile or wrap properties and, in some cases, the percent reduction in area (% R.A.) values were higher in the well-aged condition. The 500° F. exposures had no adverse effect on the tensile strength (U.T.S.) of aged wire material. An increase of up to about 30 ksi in the U.T.S. was observed for some of the cold-drawn-only wire after the 500° F. exposure.

TABLE IV

| Wire | % Cold | Aging | | 0.2% | | | | Wrap |
|---|---|---|---|---|---|---|---|---|
| Diameter | Drawn | Treatment | Exposure | Y.S. | U.T.S. | % El. | % R.A. | Test |
| 0.034 in. | 64 | 1250° F./4 h/AC | — | 331 | 335 | 2 | 26 | passed |
| ″ | 64 | 1250° F./4 h/AC | — | 324 | 328 | 1 | 21 | passed |
| ″ | 64 | 1250° F./4 h/AC | — | 324 | 331 | 1 | 26 | passed |
| ″ | 64 | 1250° F./4 h/AC | 500° F./30 days | 332 | 334 | 1 | 41 | passed |
| ″ | 64 | 1250° F./4 h/AC | 500° F./30 days | 328 | 334 | 1 | 36 | passed |
| ″ | 64 | 1250° F./4 h/AC | 500° F./30 days | 323 | 328 | 1 | 31 | passed |
| 0.032 in. | 67 | 1250° F./4 h/AC | — | 355 | 358 | 1 | 46 | passed |
| ″ | 67 | 1250° F./4 h/AC | — | 331 | 344 | 1 | 54 | |
| ″ | 67 | 1250° F./4 h/AC | — | 312 | 321 | 1 | 46 | |
| ″ | 67 | 1250° F./4 h/AC | 500° F./30 days | 342 | 352 | 1 | 54 | passed |
| ″ | 67 | 1250° F./4 h/AC | 500° F./30 days | 335 | 344 | 1 | 54 | passed |
| ″ | 67 | 1250° F./4 h/AC | 500° F./30 days | 347 | 350 | 1 | 54 | passed |
| 0.0316 in. | 69 | None | — | 278 | 303 | 1 | 47 | pass |
| ″ | 69 | None | 500° F./24 h | 293 | 327 | 1 | 32 | pass |
| ″ | 69 | None | 500° F./24 h | 297 | 333 | 2 | 37 | pass |
| ″ | 69 | None | 500° F./24 h | 302 | 329 | 2 | 37 | pass |
| ″ | 69 | 1250° F./4 h/AC | — | 356 | 361 | 1 | 27 | pass |
| ″ | 69 | 1250° F./4 h/AC | — | 362 | 364 | 1 | 27 | fail |
| ″ | 69 | 1250° F./4 h/AC | — | 350 | 356 | 1 | 22 | pass |
| ″ | 69 | 1250° F./4 h/AC | 500° F./24 h | 350 | 354 | 1 | 43 | pass |
| ″ | 69 | 1250° F./4 h/AC | 500° F./24 h | 349 | 352 | 1 | 33 | pass |
| ″ | 69 | 1250° F./4 h/AC | 500° F./24 h | 352 | 356 | 1 | 43 | pass* |
| ″ | 69 | 1300° F./4 h/AC | — | 325 | 337 | 1 | 32 | pass |
| ″ | 69 | 1300° F./4 h/AC | — | 321 | 334 | 1 | 27 | pass |
| ″ | 69 | 1300° F./4 h/AC | — | 343 | 347 | 1 | 33 | pass |
| ″ | 69 | 1300° F./4 h/AC | 500° F./24 h | 342 | 347 | 1 | 28 | pass |
| 0.0316 in. | 69 | 1300° F./4 h/AC | 500° F./24 h | 343 | 346 | 1 | 27 | pass |
| ″ | 69 | 1300° F./4 h/AC | 500° F./24 h | 332 | 337 | 1 | 32 | pass |
| 0.0293 in. | 73 | None | — | 263 | 306 | 1 | 44 | pass |
| ″ | 73 | None | 500° F./24 h | 322 | 334 | 1 | 48 | pass |
| ″ | 73 | None | 500° F./24 h | 314 | 335 | 2 | 43 | pass |
| ″ | 73 | None | 500° F./24 h | 300 | 316 | 2 | 48 | pass |
| ″ | 73 | 1250° F./4 h/AC | — | 366 | 370 | 1 | 38 | fail |
| ″ | 73 | 1250° F./4 h/AC | — | 362 | 365 | 1 | 38 | pass |
| ″ | 73 | 1250° F./4 h/AC | — | 358 | 366 | 1 | 38 | pass |
| ″ | 73 | 1250° F./4 h/AC | 500° F./24 h | 325 | 350 | 1 | 27 | pass |
| ″ | 73 | 1250° F./4 h/AC | 500° F./24 h | 347 | 354 | 1 | 27 | pass |
| ″ | 73 | 1250° F./4 h/AC | 500° F./24 h | 343 | 352 | 1 | 27 | pass |
| ″ | 73 | 1300° F./4 h/AC | — | 352 | 357 | 2 | 43 | pass |
| ″ | 73 | 1300° F./4 h/AC | — | 342 | 353 | 1 | 38 | pass |
| ″ | 73 | 1300° F./4 h/AC | — | 353 | 356 | 1 | 43 | pass |
| ″ | 73 | 1300° F./4 h/AC | 500° F./24 h | 333 | 344 | 1 | 33 | pass |
| ″ | 73 | 1300° F./4 h/AC | 500° F./24 h | 344 | 349 | 1 | 27 | pass |
| ″ | 73 | 1300° F./4 h/AC | 500° F./24 h | 337 | 346 | 1 | 33 | Pass |
| 0.0263 in. | 78 | None | — | 286 | 320 | 1 | 53 | Pass |
| ″ | 78 | None | 500° F./24 h | 331 | 344 | 2 | 42 | Fail |
| ″ | 78 | None | 500° F./24 h | 318 | 328 | 2 | 30 | fail |
| ″ | 78 | None | 500° F./24 h | 328 | 335 | 2 | 36 | fail |
| ″ | 78 | 1250° F./4 h/AC | — | 350 | 358 | 1 | 53 | fail |
| ″ | 78 | 1250° F./4 h/AC | — | 328 | 346 | 1 | 42 | fail |
| ″ | 78 | 1250° F./4 h/AC | — | 350 | 355 | 1 | 53 | fail |
| ″ | 78 | 1250° F./4 h/AC | 500° F./24 h | 333 | 350 | 1 | 48 | fail |
| ″ | 78 | 1250° F./4 h/AC | 500° F./24 h | 347 | 354 | 1 | 53 | pass |
| 0.0263 in. | 78 | 1250° F./4 h/AC | 500° F./24 h | 332 | 337 | 1 | 42 | fail |
| ″ | 78 | 1300° F./4 h/AC | — | 347 | 362 | 1 | 17 | pass |
| ″ | 78 | 1300° F./4 h/AC | — | 352 | 357 | 1 | 17 | pass |
| ″ | 78 | 1300° F./4 h/AC | — | 358 | 362 | 1 | 30 | pass |
| ″ | 78 | 1300° F./4 h/AC | 500° F./24 h | 357 | 362 | 1 | 42 | pass |
| ″ | 78 | 1300° F./4 h/AC | 500° F./24 h | 337 | 354 | 1 | 36 | pass |
| ″ | 78 | 1300° F./4 h/AC | 500° F./24 h | 347 | 349 | 1 | 36 | pass |

The effects of the various combinations of cold reduction and aging temperature on both tensile strength and wrap test ductility are illustrated in the drawing figure. Lower amounts of cold reduction in combination with lower aging temperatures resulted in high U.T.S. levels of 330-360 ksi, but with a greater number of wrap test failures. Aging temperatures higher than 1300° F. resulted in lower tensile strength. However, aging the wire at 1300° F. for 4 hours resulted in consistently good wrap test performance at U.T.S. levels up to about 360 ksi. The best combinations of properties were obtained with cold reductions of about 67-78%.

### Example 2

In a second set of tests, wire from another production heat of the UNS R00035 alloy was processed into fine wire. The heat chemistry of the additional wire material (Example 2) is presented in Table I above. The wire was cold drawn 68% R.C.S.A. to 0.031″ in diameter. The cold drawn wire was aged at various combinations of temperature and time as shown in Table V. Also, set forth in Table V are the results of room temperature tensile and wrap tests including the 0.2% offset yield strength (0.2% Y.S.) and the ultimate tensile strength (U.T.S.) in ksi, the percent elongation (% El.), the percent reduction in area (% R.A.), together with an indication whether the wire passed or failed the wrap test (Wrap Test). The aging heat treatment given to each test sample is shown in the column labeled “Age Treatment”. Some of the wire samples were given underaging heat treatments at 600° F. and 750° F., respectively, for 4 hours. The underaged samples were evaluated to determine if the desired properties could be achieved. The results for the underaged samples are also shown in Table V. The data presented in Table V confirm that the combination of at least about 325 ksi U.T.S. with acceptable wrap test ductility is obtained for the 68% cold-drawn samples aged at 1250-1325° F., although the most consistent results are obtained when the wire is aged at 1300° F. While two of the underaged samples provided acceptable results, most of the underaged samples did not achieve the desired combination of properties.

TABLE V

| Wire | % Cold | Aging | | | | | Wrap |
|---|---|---|---|---|---|---|---|
| Diameter | Drawn | Treatment | 0.2% Y.S. | U.T.S. | % El. | % R.A. | Test |
| 0.0312 in. | 68% | 600° F./4 h/AC | 318 | 324 | 1 | 14 | failed |
| ″ | ″ | ″ | 313 | 332 | 1 | 19 | passed |
| ″ | ″ | ″ | 309 | 327 | 2 | 14 | passed |
| ″ | ″ | 750° F./4 h/AC | 342 | 347 | 1 | 14 | failed |
| ″ | ″ | ″ | 286 | 298 | 1 | 13 | failed |
| ″ | ″ | ″ | 276 | 284 | 1 | 14 | failed |
| ″ | ″ | 1250° F./1 h/AC | 332 | 346 | 1 | 30 | failed |
| ″ | ″ | ″ | 336 | 339 | 1 | 35 | passed |
| ″ | ″ | ″ | 323 | 335 | 1 | 46 | failed |
| ″ | ″ | 1250° F./4 h/AC | 337 | 339 | 1 | 25 | failed |
| ″ | ″ | ″ | 324 | 328 | 1 | 25 | passed |
| ″ | ″ | ″ | 341 | 345 | 1 | 25 | failed |
| ″ | ″ | 1275° F./1 h/AC | 335 | 349 | 2 | 25 | failed |
| ″ | ″ | ″ | 315 | 341 | 1 | 19 | passed |
| ″ | ″ | ″ | 340 | 347 | 1 | 19 | passed |
| ″ | ″ | 1275° F./4 h/AC | 334 | 339 | 1 | 40 | passed |
| ″ | ″ | ″ | 328 | 340 | 1 | 25 | passed |
| ″ | ″ | ″ | 320 | 344 | 1 | 36 | passed |
| ″ | ″ | 1300° F./1 h/AC | 329 | 342 | 1 | 41 | passed |
| ″ | ″ | ″ | 330 | 335 | 1 | 30 | passed |
| 0.0312 in. | ″ | ″ | 329 | 340 | 1 | 30 | passed |
| ″ | ″ | 1300° F./4 h/AC | 336 | 337 | 1 | 33 | passed |
| ″ | ″ | ″ | 336 | 338 | 1 | 25 | passed |
| ″ | ″ | ″ | 321 | 333 | 1 | 41 | passed |
| ″ | ″ | 1325° F./1 h/AC | 339 | 340 | 1 | 25 | passed |
| ″ | ″ | ″ | 288 | 324 | 1 | 19 | passed |
| ″ | ″ | ″ | 324 | 331 | 1 | 19 | passed |
| ″ | ″ | 1325° F./4 h/AC | 301 | 304 | 1 | 25 | passed |
| ″ | ″ | ″ | 305 | 306 | 2 | 25 | passed |
| ″ | ″ | ″ | 303 | 308 | 1 | 31 | passed |

The effects of heating rate and aging time were evaluated using additional samples of the 68% cold-drawn wire. Table VI shows the results of room temperature tensile and wrap tests including the 0.2% offset yield strength (0.2% Y.S.) and the ultimate tensile tensile strength (U.T.S.) in ksi, the percent elongation (% El.), the percent reduction in area (% R.A.), together with an indication whether the wire passed or failed the wrap test (Wrap Test). The aging heat treatment given to each test sample is shown in the column labeled “Age Treatment”. The data presented in Table VI show that the best combination of properties is obtained by aging at about 1300° F. for 4 hours.

TABLE VI

| | | | | | | | |
|---|---|---|---|---|---|---|---|
| Wire | % Cold | | 0.2% | | | | |
| Diameter | Drawn | Aging Treatment | Y.S. | U.T.S. | % El. | % R.A. | Wrap Test |

Effects of Slow Heating

| | | | | | | | |
|---|---|---|---|---|---|---|---|
| 0.0312 in. | 68% | slow heat 900-1250° F. (2 h), | 336 | 340 | 1 | 30 | Passed |
| | | 1250-1300° F. (3.5 h)/AC | | | | | |
| ″ | ″ | slow heat 900-1250° F. (2 h), | 347 | 351 | 1 | 30 | Passed |
| | | 1250-1300° F. (3.5 h)/AC | | | | | |
| ″ | ″ | slow heat 900-1250° F. (2 h), | 350 | 352 | 1 | 25 | Failed |
| | | 1250-1300° F. (3.5 h)/AC | | | | | |
| ″ | ″ | slow heat 900-1225° F. (4 h), | 331 | 341 | 2 | 19 | Passed |
| | | 1225-1275° F. (7 h)/AC | | | | | |
| 0.0312 in. | ″ | slow heat 900-1225° F. (4 h), | 314 | 338 | 2 | 14 | Passed |
| | | 1225-1275° F. (7 h)/AC | | | | | |
| ″ | ″ | slow heat 900-1225° F. (4 h), | 330 | 336 | 1 | 19 | Passed |
| | | 1225-1275° F. (7 h)/AC | | | | | |
| ″ | ″ | slow heat 900-1250° F. (4 h), | 336 | 338 | 1 | 36 | Passed |
| | | 1250-1300° F. (7 h)/AC | | | | | |
| ″ | ″ | slow heat 900-1250° F. (4 h), | 336 | 341 | 1 | 30 | Passed |
| | | 1250-1300° F. (7 h)/AC | | | | | |
| ″ | ″ | slow heat 900-1250° F. (4 h), | 337 | 342 | 1 | 30 | Passed |
| | | 1250-1300° F. (7 h)/AC | | | | | |
| ″ | ″ | slow heat 900-1250° F. (4 h), | 337 | 339 | 1 | 25 | Passed |
| | | 1250-1300° F. (7 h)/4 h/AC | | | | | |
| ″ | ″ | slow heat 900-1250° F. (4 h), | 315 | 337 | 1 | 25 | Passed |
| | | 1250-1300° F. (7 h)/4 h/AC | | | | | |
| ″ | ″ | slow heat 900-1250° F. (4 h), | 331 | 337 | 1 | 26 | Passed |
| | | 1250-1300° F. (7 h)/4 h/AC | | | | | |
| ″ | ″ | slow heat 900-1250° F. (6 h), | 330 | 331 | 1 | 30 | Passed |
| | | 1250-1300° F. (10 h)/AC | | | | | |
| ″ | ″ | slow heat 900-1250° F. (6 h), | 328 | 329 | 1 | 25 | Passed |
| | | 1250-1300° F. (10 h)/AC | | | | | |
| ″ | ″ | slow heat 900-1250° F. (6 h), | 333 | 335 | 1 | 26 | Passed |
| | | 1250-1300° F. (10 h)/AC | | | | | |

Effects of Aging Time

| | | | | | | | |
|---|---|---|---|---|---|---|---|
| 0.0312 in. | ″ | 1300° F./5 minutes/AC | 323 | 343 | 1 | 19 | Failed |
| ″ | ″ | ″ | 354 | 356 | 1 | 13 | Passed |
| ″ | ″ | ″ | 319 | 341 | 1 | 19 | Passed |
| ″ | ″ | 1300° F./15 minutes/AC | 276 | 338 | 1 | 19 | Failed |
| ″ | ″ | ″ | 335 | 355 | 1 | 13 | Failed |
| ″ | ″ | ″ | 307 | 343 | 1 | 19 | Passed |
| ″ | ″ | 1300° F./30 minutes/AC | 349 | 349 | 1 | 25 | Failed |
| ″ | ″ | ″ | 329 | 347 | 2 | 19 | Passed |
| ″ | ″ | ″ | 317 | 344 | 1 | 25 | Passed |
| ″ | ″ | 1300° F./1 h/AC | 329 | 342 | 1 | 41 | Passed |
| ″ | ″ | ″ | 330 | 335 | 1 | 30 | Passed |
| ″ | ″ | ″ | 329 | 340 | 1 | 30 | Passed |
| ″ | ″ | 1300° F./2 h/AC | 324 | 342 | 1 | 30 | Passed |
| ″ | ″ | ″ | 334 | 340 | 3 | 19 | passed |
| 0.0312 in. | ″ | ″ | 348 | 348 | 2 | 13 | failed |
| ″ | ″ | 1300° F./4 h/AC | 336 | 337 | 1 | 33 | passed |
| ″ | ″ | ″ | 336 | 338 | 1 | 25 | passed |
| ″ | ″ | ″ | 321 | 333 | 1 | 41 | passed |
| ″ | ″ | 1300° F./8 h/AC | 315 | 330 | 2 | 25 | passed |
| ″ | ″ | ″ | 299 | 333 | 1 | 19 | passed |
| ″ | ″ | ″ | 289 | 329 | 3 | 25 | passed |
| ″ | ″ | 1300° F./1 h + | 315 | 345 | 1 | 30 | passed |
| | | 500° F./24 h | | | | | |
| ″ | ″ | 1300° F./1 h + | 317 | 331 | 1 | 36 | passed |
| | | 500° F./24 h | | | | | |
| ″ | ″ | 1300° F./1 h + | 342 | 348 | 1 | 25 | passed |
| | | 500° F./24 h | | | | | |
| ″ | ″ | 1300° F./4 h + | 341 | 345 | 1 | 30 | passed |
| | | 500° F./24 h | | | | | |
| ″ | ″ | 1300° F./4 h + | 323 | 340 | 1 | 25 | passed |
| | | 500° F./24 h | | | | | |
| ″ | ″ | 1300° F./4 h + | 328 | 344 | 1 | 25 | passed |
| | | 500° F./24 h | | | | | |
| ″ | ″ | 1300° F./1 h/slow cool + | 299 | 354 | 1 | 19 | failed |
| | | 500° F./24 h | | | | | |
| ″ | ″ | 1300° F./1 h/slow cool + | 340 | 350 | 1 | 25 | passed |
| | | 500° F./24 h | | | | | |
| ″ | ″ | 1300° F./1 h/slow cool + | 312 | 355 | 1 | 25 | passed |
| | | 500° F./24 h | | | | | |

Vacuum aging trials of small coils of the 68% cold drawn wire from Example 2 were performed. Small quantities of wire were coiled onto standard production spools so that the mass was comparable to that of a typical production order. For the first trial, the furnace setpoints were reduced to 1275° F. for 2 hours to avoid overheating the wire. The first trial resulted in lower % R.A. and some susceptibility to breakage during handling for subsequent corrosion testing. The wire breakage is believed to be attributable to more severe bending of the wire for the corrosion testing in combination with surface damage from the tool used to bend the wire specimens. A second trial was conducted using the preferred set point of 1300° F. for 4 hours. Table VII shows tensile and wrap test results for the two vacuum aged trials. Although the ductility of the wire as indicated by the % Elong. and the % R.A. increased relative to the first trial, none of the 1300° F. aged test samples passed the wrap test. Since the results for the bend test for the second trial were unexpected, the wire samples were analyzed to determine the reason for the failures. The failure analysis revealed that the wrap test breaks occurred because of defects on the surfaces of the wire samples.

A third trial was performed on six additional samples of wire that was aged the same way as in the first two trials. All six test samples passed the bend test in this trial. The test results are set forth at the bottom of Table VII.

TABLE VII

| | | | | | | | |
|---|---|---|---|---|---|---|---|
| Wire | % Cold | Aging | | | | | Wrap |
| Diameter | Drawn | Treatment | 0.2% Y.S. | U.T.S. | % El. | % R.A. | Test |

First Trial

| | | | | | | | |
|---|---|---|---|---|---|---|---|
| 0.0311 in. | 68% | 1275° F./2 h/Gas | 344 | 348 | 1 | 19 | passed |
| | | Quench | | | | | |
| ″ | ″ | 1275° F./2 h/Gas | 325 | 333 | 1 | 13 | passed |
| | | Quench | | | | | |
| ″ | ″ | 1275° F./2 h/Gas | 333 | 354 | 1 | 13 | passed |
| | | Quench | | | | | |

Second Trial

| | | | | | | | |
|---|---|---|---|---|---|---|---|
| 0.0311 in. | 68% | 1300° F./4 h/Gas | 342 | 345 | 2 | 19 | failed* |
| | | Quench | | | | | |
| ″ | ″ | 1300° F./4 h/Gas | 338 | 340 | 2 | 25 | failed* |
| | | Quench | | | | | |
| ″ | ″ | 1300° F./4 h/Gas | 336 | 343 | 2 | 25 | failed* |
| | | Quench | | | | | |

Third Trial

| | | | | | | | |
|---|---|---|---|---|---|---|---|
| 0.0312 in. | 68% | 1300° F./4 h/Gas | 328 | 352 | 3 | 30 | passed |
| | | Quench | | | | | |
| ″ | ″ | 1300° F./4 h/Gas | 329 | 343 | 3 | 25 | passed |
| | | Quench | | | | | |
| ″ | ″ | 1300° F./4 h/Gas | 323 | 348 | 3 | 30 | passed |
| | | Quench | | | | | |
| ″ | ″ | 1300° F./4 h/Gas | 323 | 353 | 3 | 30 | passed |
| | | Quench | | | | | |
| ″ | ″ | 1300° F./4 h/Gas | 326 | 348 | 3 | 25 | passed |
| | | Quench | | | | | |
| ″ | ″ | 1300° F./4 h/Gas | 327 | 350 | 3 | 25 | passed |
| | | Quench | | | | | |

*Failure analysis showed that fracture initiated at wire surface defects.

The terms and expressions which are employed herein are used as terms of description and not of limitation. There is no intention in the use of such terms and expressions of excluding any equivalents of the features shown and described or portions thereof. It is recognized that various modifications are possible within the invention described and claimed herein. Thus, the present invention may suitably comprise, consist essentially of, or consist of the steps of forming, annealing, drawing, and hardening as described herein. The invention illustratively disclosed herein suitably may be practiced in the absence of any step or parameter which is not specifically disclosed herein.

What is claimed is:

1. A wire article comprising wire formed from a high strength, corrosion resistant alloy having the following composition in weight percent, about

| | |
|---|---|
| Carbon | 0.03 max. |
| Manganese | 0.15 max. |
| Silicon | 0.15 max. |
| Phosphorus | 0.015 max. |
| Sulfur | 0.010 max. |
| Chromium | 19.00-21.00 |
| Nickel | 33.00-37.00 |
| Molybdenum | 9.00-10.50 |
| Titanium | 1.00 max. |
| Boron | 0.010 max. |
| Iron | 1.00 max. |

wherein the balance of the alloy is cobalt and the usual impurities and the wire is characterized by a tensile strength in excess of 300 ksi and sufficient ductility that when the wire is wrapped to provide a coil having an inside diameter substantially equal to the diameter of the wire and then unwrapped, the wire does not crack or break.

2. A wire article as claimed in claim 1 that provides a tensile strength of at least about 310 ksi.

3. A wire article as claimed in claim 1 having a diameter of about 0.0263 in. to about 0.040 in.

4. A wire article as claimed in claim 1 or claim 2 that provides ductility characterized by 1 to 4% elongation and 13 to 67% reduction in area.

5. Flexible armor for encasing a communication cable comprising spirally-wound wire as claimed in claim 1.

6. Flexible armor for encasing a communication cable comprising spirally-wound wire as claimed in claim 2.

7. Flexible armor for encasing a communication cable comprising spirally-wound wire as claimed in claim 3.

8. Flexible armor for encasing a communication cable comprising spirally-wound wire as claimed in claim 4.

9. A wire article as claimed in claim 1 that provides a tensile strength of at least about 325 ksi.
